(19) United States
(12) Patent Application Publication
(10) Pub. No.: US 2026/0059785 A1
(43) Pub. Date: Feb. 26, 2026

(54) SEMICONDUCTOR STRUCTURE

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/889,271

(22) Filed: Sep. 18, 2024

(30) Foreign Application Priority Data
Aug. 20, 2024 (CN) 202411147068.2

(51) Int. Cl. H01L 29/778; H01L 29/20

(52) U.S. Cl. CPC H10D 30/475; H10D 62/8503

(57) ABSTRACT

A semiconductor structure includes: a substrate, a buffer layer and a multi-channel heterojunction layer which are disposed in a stacking manner, the multi-channel heterojunction layer including a first, a second, . . . , and an n-th heterojunction layers in a direction away from the substrate, where n≥2, and each heterojunction layer includes a channel layer and a barrier layer; and an n-type heavily doped layer, which is disposed on a side wall of the multi-channel heterojunction layer, the n-type heavily doped layer being a multi-layer structure. The present disclosure provides the n-type heavily doped layer with the multi-layer structure, which may effectively reduce an ohmic contact resistance of a source region and a drain region.

### CROSS-REFERENCE TO RELATED APPLICATIONS

The present application claims priority to Chinese Patent Application No. 202411147068.2, filed on Aug. 20, 2024, the disclosure of which is hereby incorporated by reference in its entirety.

### TECHNICAL FIELD

The present disclosure relates to the field of semiconductor technologies, and in particular, to a semiconductor structure.

### BACKGROUND

A gallium nitride (GaN) material has advantages of a large band gap and a high breakdown field strength and the like. An AlGaN/GaN heterojunction device prepared based on this has a relatively high electron mobility, and may form a high concentration two-dimensional electron gas (2DEG) at a heterojunction interface through polarization under a condition of unintentional doping. Therefore, a GaN-based high electron mobility transistor (GaN HEMT) device has a broad application prospect in the fields of microwave power and the like.

In order to further promote the application of the GaN heterojunction device, such as in the fields of larger current, higher power, lower power consumption, higher frequency, switching mode and multi-valued logic gate and the like, it is necessary to study multi-channel heterojunction materials and devices. A multi-channel AlGaN/GaN heterojunction has a higher total density of 2DEG, to make a saturation current of the device be greatly increased. For devices of power applications, the improvement of the saturation current is crucial.

A heterojunction 2DEG conductive channel at a lower layer of a multi-channel laminated semiconductor device is far away from a surface of the device, resulting in a larger contact resistance and a larger series resistance, so that a current density and power density of the device is suppressed. Therefore, it is of great significance to effectively reduce the contact resistance of the multi-channel heterojunction.

### SUMMARY

In view of this, the embodiment of the present disclosure is provided with a semiconductor structure, to reduce a contact resistance of a multi-channel heterojunction device.

According to an aspect of the present disclosure, an embodiment of the present disclosure provides a semiconductor structure, including: a substrate, a buffer layer and a multi-channel heterojunction layer which are disposed in a stacking manner, the multi-channel heterojunction layer including a first, a second, . . . , and an n-th heterojunction layers in a direction away from the substrate, where n≥2, and each heterojunction layer includes a channel layer and a barrier layer; and an n-type heavily doped layer, which is disposed on a side wall of the multi-channel heterojunction layer, the n-type heavily doped layer being a multi-layer structure.

As an optional embodiment, along a direction close to the substrate, a concentration of n-type doped ions of the multi-layer structure gradually increases.

As an optional embodiment, a material of the multi-layer structure includes an Indium (In) component, and along a direction away from the substrate, a content of the In component gradually decreases.

As an optional embodiment, an interface of the channel layer and the barrier layer in the multi-channel heterojunction layer corresponds to an interface between two adjacent layers in the multi-layer structure.

As an optional embodiment, each layer of the multi-layer structure includes a first sub-layer and a second sub-layer.

As an optional embodiment, a material of the n-type heavily doped layer includes an GaN-based alloy material with n-type heavily doped, and a material combination of the first sublayer and the second sublayer includes at least one of GaN/InGaN, GaN/AlGaN or GaN/AlInGaN.

As an optional embodiment, a material of the second sub-layer includes an In component, and along a direction away from the substrate, a content of the In component of the m-th second sub-layer is greater than a content of the In component of the (m+1)-th second sublayer, and m is an integer greater than or equal to 1.

As an optional embodiment, an interface of the channel layer and the barrier layer corresponds to an interface of the first sub-layer and the second sub-layer.

As an optional embodiment, at least the channel layer of the first heterojunction layer includes an n-type delta-doped layer.

As an optional embodiment, n-type dopant ions of the n-type delta-doped layer includes at least one of Si, Se, Ge, Sn, Te and S.

As an optional embodiment, the semiconductor structure further includes a back barrier layer provided between the buffer layer and the multi-channel heterojunction layer.

As an optional embodiment, a material of the back barrier layer includes AlGaN, and a content of an Al component in the back barrier layer gradually changes.

As an optional embodiment, in a direction away from the substrate, the content of the Al component in the back barrier layer gradually changes from 0% to 30%.

As an optional embodiment, the heterojunction layer includes an Al component, and at an interface of the channel layer and the barrier layer, a content of the Al component in the barrier layer is the same as a content of the Al component in the channel layer.

As an optional embodiment, the barrier layer includes an Al component, and in a direction away from the substrate, contents of the Al component of a plurality of the barrier layers gradually increase or decrease.

As an optional embodiment, in a direction away from the substrate, thicknesses of a plurality of the barrier layers gradually decreases.

As an optional embodiment, a side wall of a side of the n-type heavily doped layer close to the multi-channel heterojunction layer is a rough surface.

As an optional embodiment, a width of the n-type heavily doped layer gradually increases along a direction close to the substrate.

As an optional embodiment, a bottom surface of the n-type heavily doped layer is disposed in the channel layer of the first heterojunction layer or at an interface of the buffer layer and the multi-channel heterojunction layer.

As an optional embodiment, the semiconductor structure further includes: a source and a drain, which are disposed on a side of the n-type heavily doped layer away from the substrate, and are respectively disposed on two sides of the multi-channel heterojunction layer; and a gate, which is disposed on a side of the multi-channel heterojunction layer is away from the substrate, and is disposed between the source and the drain.

### BRIEF DESCRIPTION OF THE DRAWINGS

FIG. 1 is a schematic structural diagram of a semiconductor structure provided in an embodiment of the present disclosure.

FIG. 2 is a schematic structural diagram of a semiconductor structure provided in another embodiment of the present disclosure.

FIG. 3 is a schematic structural diagram of a semiconductor structure provided in another embodiment of the present disclosure.

FIG. 4 is a schematic structural diagram of a semiconductor structure provided in another embodiment of the present disclosure.

FIG. 5 is a schematic structural diagram of a semiconductor structure provided in another embodiment of the present disclosure.

FIG. 6 is a schematic structural diagram of a semiconductor structure provided in another embodiment of the present disclosure.

FIG. 7 is a schematic structural diagram of a semiconductor structure provided in another embodiment of the present disclosure.

FIG. 8 is a schematic structural diagram of a semiconductor structure provided in another embodiment of the present disclosure.

FIG. 9 is a schematic structural diagram of a semiconductor structure provided in an embodiment of the present disclosure.

FIG. 10 is a schematic structural diagram of a semiconductor structure provided in another embodiment of the present disclosure.

FIG. 11 is a schematic structural diagram of a semiconductor structure provided in another embodiment of the present disclosure.

FIG. 12 is a schematic structural diagram of a semiconductor structure provided in another embodiment of the present disclosure.

### DETAILED DESCRIPTION OF THE EMBODIMENTS

The technical solutions in the embodiments of the present disclosure will be clearly and completely described below with reference to the drawings in the embodiments of the present disclosure. All other embodiments obtained by a person having ordinary skill in the art based on the embodiments of the present disclosure without creative efforts shall fall within the protection scope of the present disclosure.

In order to reduce a contact resistance of a multi-channel heterojunction layer, the present disclosure provides a semiconductor structure, including: a substrate, a buffer layer and a multi-channel heterojunction layer which are disposed in a stacking manner, the multi-channel heterojunction layer including a first, a second, . . . , and an n-th heterojunction layers in a direction away from the substrate, where n≥2, and each heterojunction layer includes a channel layer and a barrier layer; and an n-type heavily doped layer, which is disposed on a side wall of the multi-channel heterojunction layer, the n-type heavily doped layer being a multi-layer structure. The present disclosure provides the n-type heavily doped layer with the multi-layer structure, which may effectively reduce an ohmic contact resistance of a source region and a drain region.

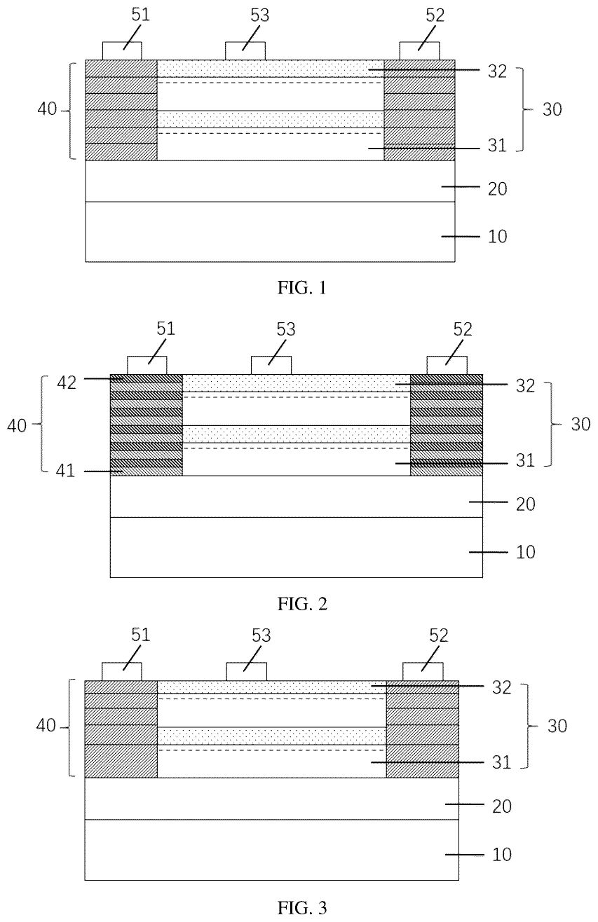

A semiconductor structure mentioned in the present disclosure is further illustrated below with reference to FIG. 1 to FIG. 12.

FIG. 1 is a schematic structural diagram of a semiconductor structure according to an embodiment of the present disclosure. As shown in FIG. 1, the semiconductor structure includes a substrate 10, a buffer layer 20 and a multi-channel heterojunction layer 30 which are disposed in a stacking manner, the multi-channel heterojunction layer 30 including a first, a second, . . . , and an n-th heterojunction layers in a direction away from the substrate, where n≥2, and each heterojunction layer includes a channel layer 31 and a barrier layer 32; and a n-type heavily doped layer 40, which is disposed on a side wall of the multi-channel heterojunction layer 30, the n-type heavily doped layer 40 being a multi-layer structure. As shown in FIG. 1, the semiconductor structure further includes a source 51 and a drain 52, which are disposed on a side of the n-type heavily doped layer 40 away from the substrate 10, and are respectively located on two sides of the multi-channel heterojunction layer 30; and a gate 53, which is disposed on a side of the multi-channel heterojunction layer 30 away from the substrate 10, and is disposed between the source 51 and the drain 52.

In the present embodiment, the substrate 10 may be sapphire, silicon carbide, silicon, GaN or diamond. A material of the buffer layer 20 may include at least one of AlN, GaN, AlGaN and AlInGaN. The buffer layer 20 may reduce a dislocation density and a defect density of an epitaxially grown semiconductor layer, and improve a quality of a crystal. Optionally, a surface of the buffer layer 20 includes a c-plane GaN layer, which may further improve the quality of the crystal of the subsequent epitaxial layer. Materials of the channel layer 31 and the barrier layer 32 may include a group III nitride, and a two-dimensional electron gas may be formed at an interface of the channel layer 31 and the barrier layer 32. In an optional solution, the channel layer 31 is a GaN layer, and the barrier layer 32 is an AlGaN layer. In other optional solutions, a material combination of the channel layer 31 and the barrier layer 32 may also be GaN/AlN, GaN/InN, GaN/InGaN, GaN/InAlGaN, GaN/InAlN or InN/InAlN. The farther the conductive channel is from the device surface in the multi-channel structure, the greater the contact resistance.

In the present embodiment, along a direction close to the substrate 10, a concentration of n-type dopant ions of the multi-layer structure gradually increases, which may effectively alleviate a problem that the farther a conductive channel is from a surface of the device in the multi-channel structure, the greater the contact resistance. A material of the multi-layer structure includes an In component, and a content of the In component gradually decreases along a direction away from the substrate 10. In the direction away from the substrate 10, the content of the In component is gradually reduced, so that a compressive stress of the semiconductor structure is gradually reduced, thus stress distribution of the semiconductor structure may be effectively adjusted and controlled, and thus a quality of the semiconductor structure is improved. In some embodiments, an interface of the channel layer 31 and the barrier layer 32 in the multi-channel heterojunction layer 30 corresponds to an interface of two adjacent layers in the multi-layer structure, which is beneficial to the two-dimensional electron gases in the n-type heavily doped layer 40 and the heterojunction structure being connected to each other, and thus the contact resistance is further reduced.

In some embodiments, referring to FIG. 2, FIG. 2 is a schematic structural diagram of a semiconductor structure according to an embodiment of the present disclosure. As shown in FIG. 2, each layer of the multi-layer structure includes a first sub-layer 41 and a second sub-layer 42. A material of the n-type heavily doped layer 40 includes a GaN-based alloy material with n-type heavily doped. A material combination of the first sub-layer 41 and the second sub-layer 42 includes at least one of GaN/InGaN, GaN/AlGaN or GaN/AlInGaN. Optionally, a material of the second sub-layer 42 includes an In component, along a direction away from the substrate 10, a content of the In component of the m-th second sub-layer 42 is greater than a content of the In component of the (m+1)-th second sub-layer 42, where m is an integer greater than or equal to 1. In the direction away from the substrate 10, the content of the In component is gradually reduced, so that the compressive stress of the semiconductor structure is gradually reduced, which may effectively adjust and control the stress distribution of the semiconductor structure, and thus the quality of the semiconductor structure is improved. The arrangement of the n-type heavily doped layer 40 may effectively reduce a contact resistance between the multi-channel heterojunction layer 30 and an electrode, and optionally, the interface of the channel layer 31 and the barrier layer 32 corresponds to the interface of the first sub-layer 41 and the second sub-layer 42 in the n-type heavily doped layer 40, which is beneficial to the two-dimensional electron gases in the n-type heavily doped layer 40 and the heterojunction structure being connected to each other, and thus the contact resistance is further reduced. Optionally, in a same layer of the multi-layer structure, a thickness of the first sub-layer 41 is greater than a thickness of the second sub-layer 42.

In some embodiments, the heterojunction layer includes an Al component, and at an interface of the channel layer 31 and the barrier layer 32, a concentration of the Al component in the barrier layer 32 is the same as a concentration of the Al component in the channel layer 31. Optionally, in the direction away from the substrate 10, the concentrations of the Al component of each of the barrier layers 32 firstly increases and then decreases or change periodically. A change manner of the concentrations of the Al component of each of the barrier layers 32 is not specifically limited in the present disclosure, as long as the concentration of the Al component in the barrier layer 32 is the same as the concentration of the Al component in the channel layer 31 at the interface. The concentration of the Al component of the barrier layer 32 is controlled to be the same as the concentration of the Al component in the channel layer 31 at the interface, on one aspect, lattice mismatch of the channel layer 31 and the barrier layer 32 may be reduced, so that a quality of lattices of the materials of the channel layer 31 and the barrier layer 32 is improved; and on the other aspect, since there is no component difference at the interface of the barrier layer 32 and the channel layer 31, spontaneous polarization and piezoelectric polarization at the interface are reduced, so that a concentration of the two-dimensional electron gas at the interface is effectively reduced, and thus a gentle conduction band lower than a Fermi level is formed at the interface, which is beneficial to improve control capability of the gate of the semiconductor structure. Optionally, the barrier layer 32 includes an Al component, and in a direction away from the substrate 10, concentrations of the Al component of a plurality of the barrier layers 32 gradually increase or gradually decrease, so that a uniformity of concentrations of the overall two-dimensional electron gases of the semiconductor structure may be adjusted and controlled by adjusting and controlling the concentrations of the Al component of the plurality of the barrier layers 32.

In some embodiments, referring to FIG. 3, FIG. 3 is a schematic structural diagram of a semiconductor structure according to an embodiment of the present disclosure. As shown in FIG. 3, a difference between the semiconductor structure in this embodiment and the structures shown in FIG. 1 and FIG. 2 is that: thicknesses of the plurality of the barrier layers 32 gradually decrease in the direction away from the substrate 10. The thickness of the barrier layer 32 away from the substrate 10 is reduced, such that a thickness of the multi-channel heterojunction layer 30 is reduced, that is, a distance between the heterojunction layer which is farthest from the electrode and the electrode is reduced, so that control capability of the gate 53 on the first heterojunction layer is improved. At the same time, the farther away from the electrode, the greater the thickness of the barrier layer 32 of the heterojunction layer, so that the concentration of the two-dimensional electron gas of this heterojunction layer is improved, and thus the contact resistance between the heterojunction layer which is far away from the electrode and the electrode is reduced. The heterojunction layer changes corresponding to the multi-layer structure, in the direction away from the substrate 10, the thicknesses of the plurality of the barrier layers 32 gradually decreases. Meanwhile, in the direction away from the substrate 10, a thickness of the m-th layer of the multi-layer structure is greater than a thickness of the (m+1)-th layer, where m is an integer greater than or equal to 1, that is, in the direction away from the substrate 10, the thicknesses of the layers of multi-layer structure gradually decrease. Optionally, in the direction away from the substrate 10, a thickness of the m-th second sub-layer 42 is greater than a thickness of the (m+1)-th second sub-layer 42, where m is an integer greater than or equal to 1, that is, in the direction away from the substrate 10, the thicknesses of the plurality of second sub-layers 42 gradually decrease.

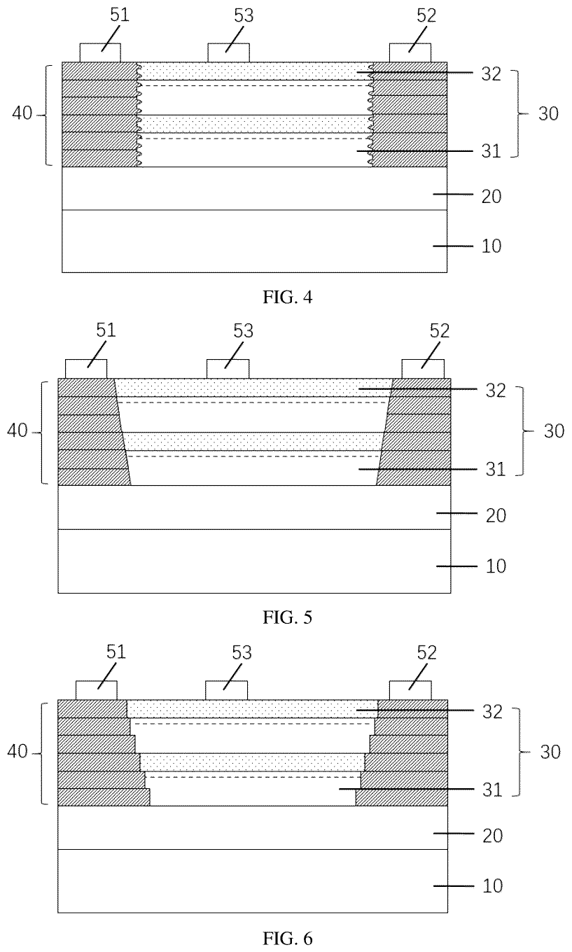

In some embodiments, referring to FIG. 4, FIG. 4 is a schematic structural diagram of a semiconductor structure according to an embodiment of the present disclosure. As shown in FIG. 4, a difference between the semiconductor structure in this embodiment and the structures shown in FIG. 1 to FIG. 3 is that: a sidewall of a side of the n-type heavily doped layer 40 close to the multi-channel heterojunction layer 30 is a rough surface. Compared with a smooth side wall of the n-type heavily doped layer 40 shown in FIG. 1 to FIG. 3, the side wall of the n-type heavily doped layer 40 is a rough surface may further increase a contact area between the N-type heavily doped layer 40 and the multi-channel heterojunction layer 30, thereby the contact resistance between the n-type heavily doped layer 40 and the two-dimensional electron gas is reduced, and thus a total contact resistance in the semiconductor structure is reduced.

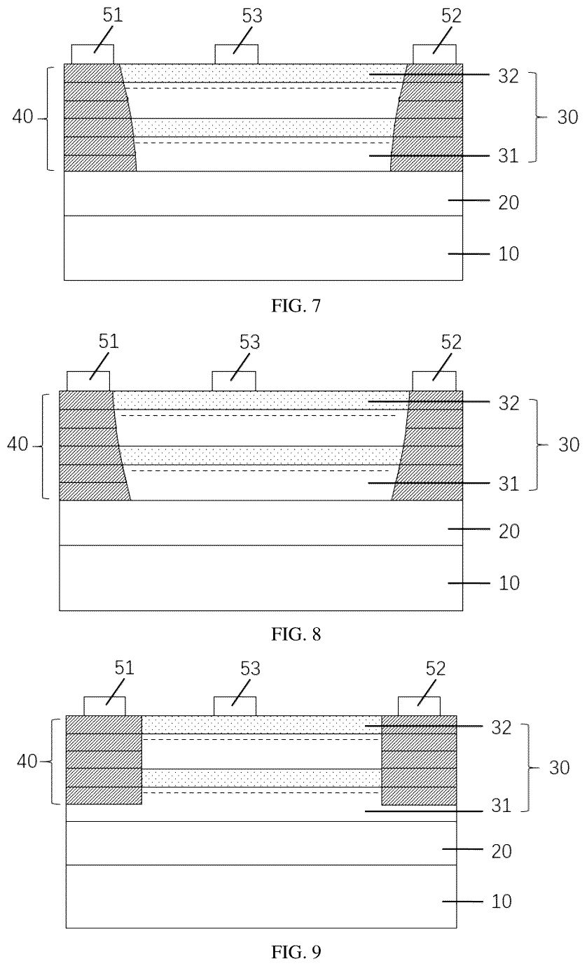

In some embodiments, referring to FIG. 5 to FIG. 8, FIG. 5 to FIG. 8 are schematic structural diagrams of a semiconductor structure provided in some embodiments of the present disclosure. As shown in FIG. 5, a width of the n-type heavily doped layer 40 gradually increases along a direction close to the substrate 10. That is, in the direction close to the substrate 10, the channel structure 20 is a trapezoid with a narrow top and a wide bottom. A included angle between the side wall of the n-type heavily doped layer 40 and a plane where the substrate 10 is located may range from 40 degrees to 89 degrees, for example, 85 degrees, 80 degrees, 75 degrees, 70 degrees or 65 degrees or the like. Compared with the semiconductor structures in which the n-type heavily doped layer 40 is not slantwise arranged as shown in FIG. 1 to FIG. 3, in the present embodiment, the n-type heavily doped layer 40 with a lower bulk resistance is used for more replacing the channel layer 31 which is farther away from the surface of the device, which better solves the problem that the farther the conductive channel is from the surface of the device in the multi-channel structure, the greater the contact resistance, thereby a performance of the semiconductor structure is improved. In the semiconductor structure shown in FIG. 5, a width of the n-type heavily doped layer 40 is uniformly increased along a direction close to the substrate 10, and optionally, as shown in FIG. 6, the width of the n-type heavily doped layer 40 is increased in a step shape along the direction close to the substrate 10, and an interface of the barrier layer 32 and channel layer 31 of each heterojunction layer is flush with a surface of the step of the n-type heavily doped layer 40, which is beneficial to the n-type heavily doped layer 40 and the two-dimensional electron gas in the heterojunction be connected to each other, thereby the ohmic contact resistance is effectively reduced, and thus the total contact resistance in the semiconductor structure is further reduced. In the semiconductor structure shown in FIG. 5, the side wall of the n-type heavily doped layer 40 is an inclined flat plane. Optionally, as shown in FIG. 7, the side wall of the n-type heavily doped layer 40 is an inclined outer convex curved surface, or, as shown in FIG. 8, the side wall of the n-type heavily doped layer 40 is an inclined inner convex curved surface. The side wall of the n-type heavily doped layer 40 is a curved surface, which may further increase the contact area between the n-type heavily doped layer 40 and the multi-channel heterojunction layer 30, thereby the contact resistance of the n-type heavily doped layer 40 and the two-dimensional electron gas is reduced, and thus the total contact resistance in the semiconductor structure is reduced.

In some embodiments, referring to FIG. 9, FIG. 9 is a schematic structural diagram of a semiconductor structure according to an embodiment of the present disclosure. A bottom surface of the n-type heavily doped layer 40 is located in the channel layer 31 of the first heterojunction layer (as shown in FIG. 9) or at an interface of the buffer layer 20 and the multi-channel heterojunction layer 30 (as shown in FIG. 1).

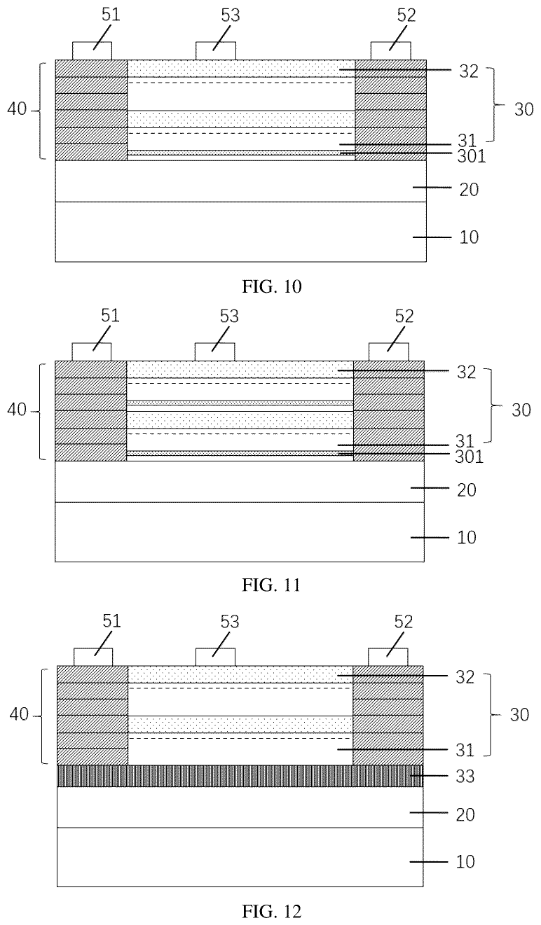

In some embodiments, referring to FIG. 10 and FIG. 11, FIG. 10 and FIG. 11 are schematic structural diagrams of a semiconductor structure provided in some embodiments of the present disclosure. As shown in FIG. 10, a difference between the semiconductor structure in this embodiment and the structures shown in FIG. 1 to FIG. 9 is that: at least the channel layer 31 in the first heterojunction layer includes an n-type delta-doped layer 301. N-type doped ions of the n-type delta-doped layer 301 include at least one of Si, Se, Ge, Sn, Te and S. The n-type delta doped layer 301 is disposed in the channel layer 31 in the first heterojunction layer, which may better solve the problem that the farther the conductive channel is from the surface of the device in the multi-channel structure, the greater the contact resistance, thereby the performance of the semiconductor structure is improved. As shown in FIG. 11, the channel layers 31 of the plurality of the heterojunction layers all include the n-type delta doped layer 301, and doping concentrations of the plurality of the n-type delta doped layers 301 decreases progressively along a direction that the substrate 10 points to the multi-channel heterojunction layer 30. Therefore, on one aspect, the contact resistance between the multi-channel heterojunction layer 30 and the electrode is reduced, and on the other aspect, an energy band structure of the channel layer of the HEMT device may be adjusted, to make a concentration of electrons in the channel below the gate is more uniform with the increase of a voltage of the gate in the semiconductor structure, and thus distortion of signal transmission and device degradation of the semiconductor structure in a high field is improved, and thus a purpose of improving a linearity of the semiconductor structure is achieved.

In an embodiment, referring to FIG. 12, FIG. 12 is a schematic structural diagram of a semiconductor structure according to an embodiment provided in the present disclosure. As shown in FIG. 12, a difference between the structure of the semiconductor structure in this embodiment and the structures shown in FIG. 1 to FIG. 11 is that: the semiconductor structure further includes a back barrier layer 33 provided between the buffer layer 20 and the multi-channel heterojunction layer 30. A material of the back barrier layer 33 includes AlGaN, a content of an Al component in the back barrier layer 33 gradually changes, and in the direction away from the substrate 10, the content of the Al component in the back barrier layer 33 is gradually changed from 0% to 30%. The back barrier layer 33 of which the content of the Al component is gradually changed may suppress a leakage current caused by drift of electrons in the channel under a large voltage to the back barrier layer.

The present disclosure provides a semiconductor structure, including a substrate, a buffer layer and a multi-channel heterojunction layer which are disposed in a stacking manner, the multi-channel heterojunction layer including a first, a second, . . . , and an n-th heterojunction layers in a direction away from the substrate, where n≥2, and each heterojunction layer includes a channel layer and a barrier layer; and an n-type heavily doped layer, which is disposed on a side wall of the multi-channel heterojunction layer, the n-type heavily doped layer being a multi-layer structure. According to the present disclosure, on one aspect, the n-type heavily doped layer of the multi-layer structure is provided, so that the ohmic contact resistance of the source region and drain region may be effectively reduced, on the other aspect, the interface of the heterojunction layer is disposed corresponding to the interface of the multi-layer structure, so that the contact resistance may be further reduced, and on yet other aspect, the width of the n-type heavily doped layer is varied, so that the contact area of the n-type heavily doped layer and the multi-channel heterojunction layer may be increased, and thus the contact resistance is further reduced.

It should be understood that the term “include” and its variants used in the present disclosure are open-ended inclusion, that is, “include but not limited to”. The term “one embodiment” means “at least one embodiment”; the term “another embodiment” means “at least one other embodiment”. In this specification, the schematic expression of the above-mentioned terms does not necessarily refer to the same embodiment or example. Furthermore, the particular features, structures, materials, or characteristics described may be combined in any one or more embodiments or examples in any suitable manner. In addition, different embodiments or examples described in this specification and features of different embodiments or examples may be combined and combined by a person having ordinary skill in the art without contradicting each other.

The foregoing are merely preferred embodiments of the present disclosure and are not intended to limit the present disclosure. Any modification and equivalent replacement and the like made within the spirit and principle of the present disclosure should be included in the protection scope of the present disclosure.

What is claimed is:

1. A semiconductor structure, comprising:
a substrate, a buffer layer and a multi-channel heterojunction layer which are disposed in a stacking manner, the multi-channel heterojunction layer comprising a first, a second, . . . , and an n-th heterojunction layers in a direction away from the substrate, wherein n≥2, and each heterojunction layer comprises a channel layer and a barrier layer; and
an n-type heavily doped layer, which is disposed on a side wall of the multi-channel heterojunction layer, the n-type heavily doped layer being a multi-layer structure.

2. The semiconductor structure according to claim 1, wherein along a direction close to the substrate, a concentration of n-type doped ions of the multi-layer structure gradually increases.

3. The semiconductor structure according to claim 1, wherein a material of the multi-layer structure comprises an Indium (In) component, and along a direction away from the substrate, a content of the In component gradually decreases.

4. The semiconductor structure according to claim 1, wherein an interface of the channel layer and the barrier layer in the multi-channel heterojunction layer corresponds to an interface between two adjacent layers in the multi-layer structure.

5. The semiconductor structure according to claim 1, wherein each layer of the multi-layer structure comprises a first sub-layer and a second sub-layer.

6. The semiconductor structure according to claim 5, wherein a material of the n-type heavily doped layer comprises a GaN-based alloy material with n-type heavily doped, and a material combination of the first sub-layer and the second sub-layer comprises at least one of GaN/InGaN, GaN/AlGaN or GaN/AlInGaN.

7. The semiconductor structure according to claim 5, wherein a material of the second sub-layer comprises an In component, along a direction away from the substrate, a content of the In component of the m-th second sub-layer is greater than a content of the In component of the (m+1)-th second sub-layer, and m is an integer greater than or equal to 1.

8. The semiconductor structure according to claim 5, wherein an interface of the channel layer and the barrier layer corresponds to an interface of the first sub-layer and the second sub-layer.

9. The semiconductor structure according to claim 1, wherein at least the channel layer of the first heterojunction layer comprises an n-type delta-doped layer.

10. The semiconductor structure according to claim 9, wherein n-type doped ions of the n-type delta-doped layer comprise at least one of Si, Se, Ge, Sn, Te and S.

11. The semiconductor structure according to claim 1, further comprising a back barrier layer provided between the buffer layer and the multi-channel heterojunction layer.

12. The semiconductor structure according to claim 11, wherein a material of the back barrier layer comprises AlGaN, and a content of an Al component in the back barrier layer gradually changes.

13. The semiconductor structure according to claim 12, wherein in a direction away from the substrate, the content of the Al component in the back barrier layer gradually changes from 0% to 30%.

14. The semiconductor structure according to claim 1, wherein the heterojunction layer comprises an Al component, and at an interface of the channel layer and the barrier layer, a content of the Al component in the barrier layer is the same as a content of the Al component in the channel layer.

15. The semiconductor structure according to claim 1, wherein the barrier layer comprises an Al component, and in a direction away from the substrate, contents of the Al component of a plurality of the barrier layers gradually increase or decrease.

16. The semiconductor structure according to claim 1, wherein in a direction away from the substrate, thicknesses of a plurality of the barrier layers gradually decrease.

17. The semiconductor structure according to claim 1, wherein a side wall of a side of the n-type heavily doped layer close to the multi-channel heterojunction layer is a rough surface.

18. The semiconductor structure according to claim 1, wherein a width of the n-type heavily doped layer gradually increases along a direction close to the substrate.

19. The semiconductor structure according to claim 1, wherein a bottom surface of the n-type heavily doped layer is disposed in the channel layer of the first heterojunction layer or at an interface of the buffer layer and the multi-channel heterojunction layer.

20. The semiconductor structure according to claim 1, further comprising:
a source and a drain, which are disposed on a side of the n-type heavily doped layer away from the substrate, and are respectively disposed on two sides of the multi-channel heterojunction layer; and
a gate, which is disposed on a side of the multi-channel heterojunction layer away from the substrate, and is disposed between the source and the drain.
